(19) United States
(12) Patent Application Publication
(10) Pub. No.: US 2020/0150464 A1
(43) Pub. Date: May 14, 2020

(54) OPTOELECTRONIC SWITCH FOR MACH-ZEHNDER INTERFEROMETER

(71) Applicant: Commissariat A L'Energie Atomique et aux Energies Alternatives, Paris (FR)

(72) Inventors: Benoit CHARBONNIER, Grenoble cedex 09 (FR); David FOWLER, Grenoble cedex 09 (FR)

(73) Assignee: Commissariat A L'Energie Atomique et aux Energies Alternatives, Paris (FR)

(21) Appl. No.: 16/679,717

(22) Filed: Nov. 11, 2019

(30) Foreign Application Priority Data
Nov. 12, 2018 (FR) 18 60415

(51) Int. Cl. G02F 1/01; G02B 6/293; H03K 17/14

(52) U.S. Cl. CPC G02F 1/0147; H03K 17/14; G02F 1/0118; G02B 6/29352

(57) ABSTRACT

The invention relates to an optoelectronic switch comprising:
a Mach-Zehnder interferometer (10);
a switching device (20) comprising:
   at least two thermo-optical phase-shifters (21a, 21b), and a switching module (22) designed to apply a continuous signal, referred to as switching signal, of constant intensity to the thermo-optical phase-shifters (21a, 21b);
   at least two electro-refractive phase-shifters (23a, 23b), and a compensation module (24) designed to apply a transient signal, referred to as compensation signal, of variable intensity to the electro-refractive phase-shifters (23a, 23b).

### TECHNICAL FIELD

The field of the invention is that of optoelectronic switches of the Mach-Zehnder type which may be used in photonic integrated circuits, notably in the framework of photonics on silicon.

### PRIOR ART

Photonic integrated circuits (or PICs) are formed from active photonic components (switches, modulators, diodes, etc.) and passive photonic components (waveguides, multiplexers, etc.) optically coupled together. Optoelectronic switches are notably used in the framework of the routing of optical signals. They may be of the Mach-Zehnder interferometer type or of the resonant ring type. Mach-Zehnder interferometers, although having a larger surface area within the PIC circuit than that of resonant ring interferometers, have the advantage of having a broad spectral band of operation (broadband operation).

The Mach-Zehnder interferometer of the optoelectronic switch is usually a 2×2 interferometer comprising an input coupler with two input ports designed to receive an incoming optical signal, an output coupler having two output ports designed to supply the outgoing optical signal, the two couplers being connected together via two separate waveguides, referred to as arms, within which optical signals coming from the same incoming optical signal propagate.

With the aim of switching the outgoing optical signal from one to the other of the two output ports, an optical phase-shifter is disposed on at least one of the arms, which allows a variation in the phase of the optical signal propagating in the arm in question to be generated, and thus a difference in phase between the optical signals received by the output coupler to be generated. Depending on the constructive or destructive interference effects between the optical signals propagating in the arms, the outgoing optical signal will be supplied via one or the other of the ports of the output coupler.

The optical phase-shifter conventionally uses an electro-refractive or a thermo-optical effect. In both cases, the variation of the phase is obtained by a variation of the index of refraction of the material forming the core of the waveguide in question. This modification of the index of refraction may be obtained by modification of the density of free carriers in the case of the electro-refractive phase-shifter, or by modification of the temperature applied to the arm in the case of the thermo-optical phase-shifter.

Generally speaking, such an optoelectronic switch of the Mach-Zehnder type must have a good performance, notably in terms of switching time, of insertion losses, and of optical isolation between the ports of the output coupler.

The switching time is the amount of time required for the majority of the optical intensity to switch from one to the other of the output ports. It may be of the order of a few nanoseconds in the case of an electro-refractive phase-shifter or of the order of a few microseconds in the case of a thermo-optical phase-shifter.

The insertion losses (IL) here represent the optical losses associated with the switch and depend on the ratio Iᵢₙ/Iₒᵤₜ between the optical intensity Iᵢₙ of the incoming optical signal over the optical intensity Iₒᵤₜ of the outgoing optical signal in the absence of optical crosstalk (in other words when the optical intensity is maximum on the selected port (state ON) of the output coupler and minimum on the unselected port (state OFF)).

The optical isolation between the ports of the output coupler is evaluated by the extinction ratio (ER) which depends on the rapport I_{out,on}/I_{out,off} between the maximum optical intensity I_{out,on} obtained on a port of the output coupler in selected mode, and the minimum optical intensity I_{out,off} obtained on this same port in unselected mode. A poor optical isolation between the ports, which results in the presence of an unwanted optical signal on the unselected port of the output coupler, is representative of the optical crosstalk phenomenon which comes notably from an imbalance between the optical losses in the arms.

The Patent application US2017/0293200 describes a switch of the Mach-Zehnder type using an electro-refractive phase-shifter to provide the switching of the optical signal from one to the other of the output ports, and exhibiting a short switching time together with a reduced optical crosstalk. For this purpose, as FIG. 1A illustrates, the switch 1 comprises a Mach-Zehnder interferometer 10 equipped with an electro-refractive phase-shifter 23 whose activation allows the outgoing optical signal to be switched onto one or the other of the ports 13a, 13b of the output coupler 13. With the aim of correcting an imbalance of the optical phases between the arms 12a, 12b and thus of increasing the extinction ratio ER, the switch 1 comprises a dynamic correction module 26 formed from a thermo-optical phase-shifter 21 disposed in the second arm 12b and of two photodetectors 25a, 25b optically coupled to the ports 13a, 13b of the output coupler 13. Thus, using the measurement signals transmitted by the photodetectors 25a, 25b, the thermo-optical phase-shifter 21 is more or less activated in such a manner as to compensate the phase errors between the optical signals propagating in the arms 12a, 12b, which allows the extinction ratio ER to be increased (and hence the optical crosstalk to be decreased). However, it turns out that the electro-refractive phase-shifter, although allowing a fast switching to be obtained, leads to non-negligible insertion losses together with an optical crosstalk that should be corrected. The document US2017/099529 describes one example of a switch of the Mach-Zehnder type similar to that of the Patent application US2017/0293200. Here again, the switching is provided by electro-optical phase-shifters, and thermo-optical phase-shifters are provided in order to minimize the phase errors.

The document by Matsuura et al. entitled Accelerating Switching Speed of thermo-optic MZI Silicon-Photonic Switches with ‘Turbo Pulse’ in PWM Control, Optical Fiber Communications Conference and Exhibition (OFC), 2017, illustrates another approach which consists in using thermo-optical phase-shifters to provide the switching of the optical signal from one to the other of the output ports. It describes an optoelectronic switch of the Mach-Zehnder type with low optical crosstalk and low insertion losses whose switching time is reduced. As illustrated in FIG. 1B, the Mach-Zehnder interferometer 10 comprises two thermo-optical phase-shifters 21a, 21b disposed in the arms 12a, 12b. The switching is provided by the activation of one or the other of the thermo-optical phase-shifters 21a, 21b. The latter exhibit substantially no insertion losses, such that optical losses between the arms 12a, 12b are substantially balanced, leading to a good isolation between the ports of the output coupler. The authors show that the switching time may be reduced by applying to one or the other of the thermo-optical phase-shifters 21a, 21b a switching signal having an electrical power peak followed by a return to a constant nominal value. It turns out that the variation of the temperature generated by the thermo-optical phase-shifter 21a, 21b up to the nominal switching temperature is faster, thus allowing the switching time to be reduced from around twenty microseconds to a few microseconds. However, it turns out that the switching time here remains of the order of a switching time of the thermo-optical type, in other words of the order of a few microseconds. Moreover, the control of the thermo-optical phase-shifters is relatively restrictive in that it involves the use of an electrical power peak.

### DESCRIPTION OF THE INVENTION

The aim of the invention is to overcome, at least in part, the drawbacks of the prior art and, more particularly, to provide an optoelectronic switch with low insertion losses and high extinction ratio, and exhibiting a short switching time.

For this purpose, one subject of the invention is an optoelectronic switch, comprising:
a Mach-Zehnder interferometer, comprising:
   an input coupler, comprising at least a first input port designed to receive an optical signal referred to as incoming optical signal;
   first and second waveguides referred to as arms, connected to the input coupler, designed to transmit optical signals, coming from the incoming optical signal, and able to exhibit a phase difference referred to as effective phase difference;
   an output coupler, connected to the arms, and comprising two output ports, in order to supply an optical signal referred to as outgoing optical signal,
a switching device, comprising:
   at least two thermo-optical phase-shifters disposed in the arms,
   a switching module designed to apply a continuous signal, referred to as switching signal, of constant intensity, to the thermo-optical phase-shifters, in such a manner as to generate a component referred to as thermo-optical component of the effective phase difference, which varies up to a predetermined final value resulting in a switching of the outgoing optical signal onto one or the other of the output ports.

According to the invention, the switching device furthermore comprises:
at least two electro-refractive phase-shifters disposed in the arms,
a compensation module designed to apply a transient signal, referred to as compensation signal, of variable intensity, to the electro-refractive phase-shifters, in such a manner as to generate an additional component, referred to as electro-refractive component, of the effective phase difference, the said variable intensity being determined in such a manner as to minimize the difference between the predetermined final value and the effective phase difference.

Certain preferred but non-limiting aspects of this optoelectronic switch are the following.

The switching device may furthermore comprise at least one photodetector coupled to one of the output ports and connected to the compensation module, the compensation module comprising a processor for determining, using measurement signals transmitted by the photodetector, the variable intensity to be applied in such a manner as to minimize the said difference between the predetermined final value and the effective phase difference.

The electro-refractive phase-shifters may be pin diodes, pn diodes, or carrier accumulating capacitive structures.

The arms may be made of silicon.

The Mach-Zehnder interferometer may be a 2×2 interferometer whose input coupler comprises two input ports.

The invention also relates to a method of switching an output optical signal from one to the other of the output ports of an optoelectronic switch according to any one of the preceding features, comprising the following steps:
i) application of the switching signal to the thermo-optical phase-shifters in such a manner as to generate the thermo-optical component of the effective phase difference, which varies up to the predetermined final value resulting in the switching of the outgoing optical signal;
ii) application of the transient compensation signal to the electro-optical phase-shifters in such a manner as to generate the electro-refractive component of the effective phase difference, whose variable intensity is determined in such a manner as to minimize the said difference between the predetermined final value and the effective phase difference.

The switching signal may be designed to drive a variation going from 0 to π, and vice versa, of the thermo-optical contribution of the effective phase difference, over a characteristic duration of thermo-optical variation (i.e. during this duration).

The compensation signal may be designed to drive:
a variation going from 0 to +π of the electro-refractive component of the effective phase difference, over a characteristic duration of electro-refractive variation less than the characteristic duration of thermo-optical variation,
followed by a return to 0, over a characteristic duration of variation substantially equal to the characteristic duration of thermo-optical variation.

In the absence of a phase difference between the optical signals propagating in the arms, the outgoing optical signal may be sent to the second port of the output coupler, and the switching from the second port to the first port of the output coupler may comprise the following steps:
an application of the switching signal, so that the thermo-optical component of the effective phase difference goes from 0 to π;
an application of the compensation signal, so that the electro-refractive component of the effective phase difference goes from 0 to π, then decreases down to 0 at the same time as the thermo-optical component progressively increases from 0 to π.

The application of the switching signal may amount to applying a continuous signal of constant intensity V_{TO,π} to the thermo-optical phase-shifter situated in the first arm driving a variation of π of the phase of the optical signal propagating in the first arm, and to applying to the thermo-optical phase-shifter situated in the second arm a signal of zero intensity.

The application of the compensation signal may amount to applying a transient signal of variable intensity going from 0 to a value V_{ER,π} to the electro-refractive phase-shifter situated in the first arm driving a variation of π of the phase of the optical signal propagating in the first arm, followed by a decrease to a zero value at the same time as the thermo-optical component progressively increases from 0 to π, and in applying to the electro-refractive phase-shifter situated in the second arm a signal of zero intensity.

In the absence of a phase difference between the optical signals propagating in the arms, the outgoing optical signal being sent to the second port of the output coupler, the switching from the first port to the second port of the output coupler may comprise:
an application of the switching signal, so that the thermo-optical component goes from π to 0;
an application of the compensation signal, so that the electro-refractive component goes from 0 to −π, then increases up to 0, at the same time as the thermo-optical component progressively decreases from π to 0.

The application of the switching signal may amount to applying a continuous signal of constant intensity V_{TO,π} to the thermo-optical phase-shifter situated in the first arm, and in applying a continuous signal of constant intensity V_{TO,π} to the thermo-optical phase-shifter situated in the second arm driving a variation of π of the phase of the optical signal propagating in the second arm.

The application of the compensation signal may amount to applying a signal of zero intensity to the electro-refractive phase-shifter situated in the first arm, and in applying a signal of variable intensity going from 0 to a value V_{ER,π} to the electro-refractive phase-shifter situated in the second arm driving a variation of π of the phase of the optical signal propagating in the second arm, followed by a return to a zero value at the same time as the thermo-optical component progressively decreases from π to 0.

### BRIEF DESCRIPTION OF THE DRAWINGS

Other aspects, aims, advantages and features of the invention will become more clearly apparent upon reading the following detailed description of preferred embodiments of the latter, given by way of non-limiting examples, and presented with reference to the appended drawings in which:

FIGS. 1A and 1B, already described, are schematic and partial views of various examples of optoelectronic switches according to the prior art;

FIG. 2 is a schematic and partial view of an optoelectronic switch according to one embodiment;

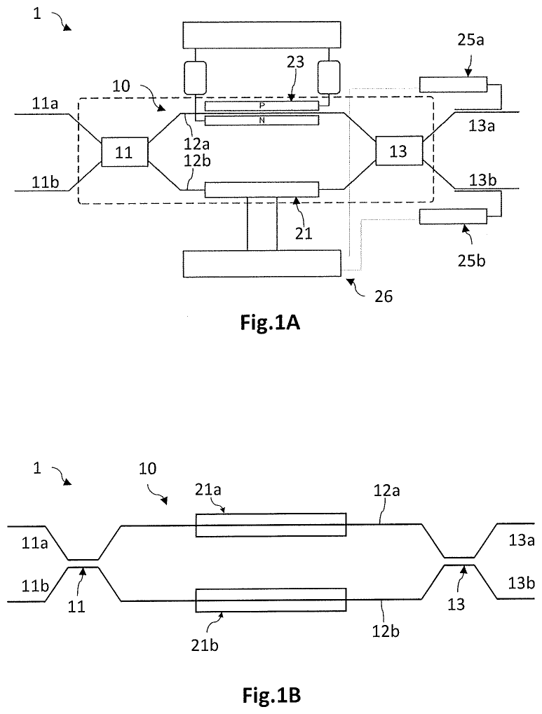

FIG. 3 illustrates the time variation:
of the switching signal V_{TOa}, V_{TOb} applied to the thermo-optical phase-shifters, and of the thermo-optical contribution Δϕ_{TO} resulting from this;
of the compensation signal V_{ERa}, V_{ERb} applied to the electro-refractive phase-shifters, and of the electro-refractive contribution Δϕ_{ER} resulting from this; and
of the effective phase difference Δϕ_{eff} corresponding to the sum of the thermo-optical component Δϕ_{TO} and of the electro-refractive component Δϕ_{ER};

FIG. 4 illustrates the time variation:
of the switching signal V_{TOa} applied to the thermo-optical phase-shifter of the first arm, and of the variation of phase ϕ_{A} resulting from this;
of the switching signal V_{TOb} applied to the thermo-optical phase-shifter of the second arm, and of the variation of phase ϕ_{B} resulting from this;
of the thermo-optical component Δϕ_{TO} resulting from this;
of the compensation signal V_{ERa}, V_{ERb} applied to the electro-refractive phase-shifters, and of the electro-refractive component Δϕ_{ER} resulting from this; and
of the effective phase difference Δϕ_{eff} corresponding to the sum of the thermo-optical component Δϕ_{TO} and of the electro-refractive component Δϕ_{ER};

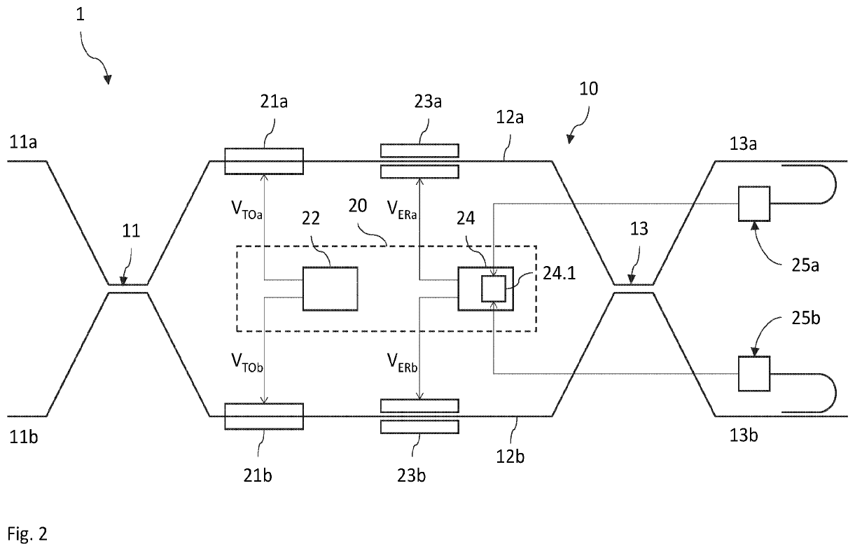

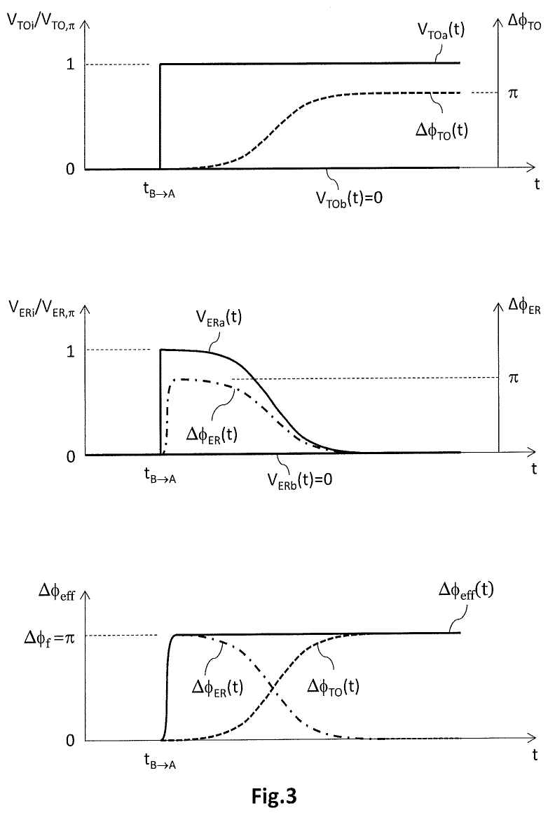

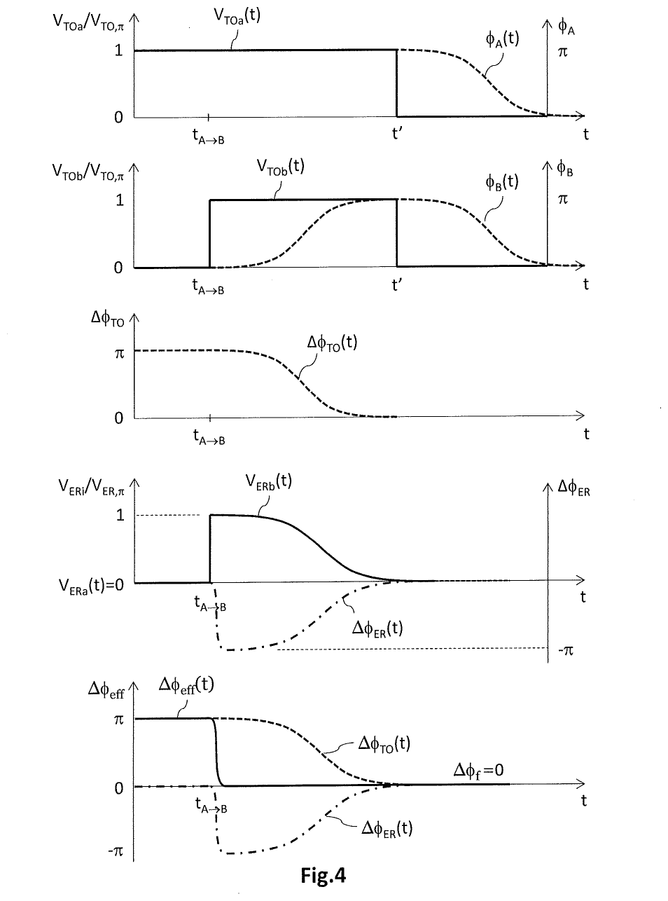

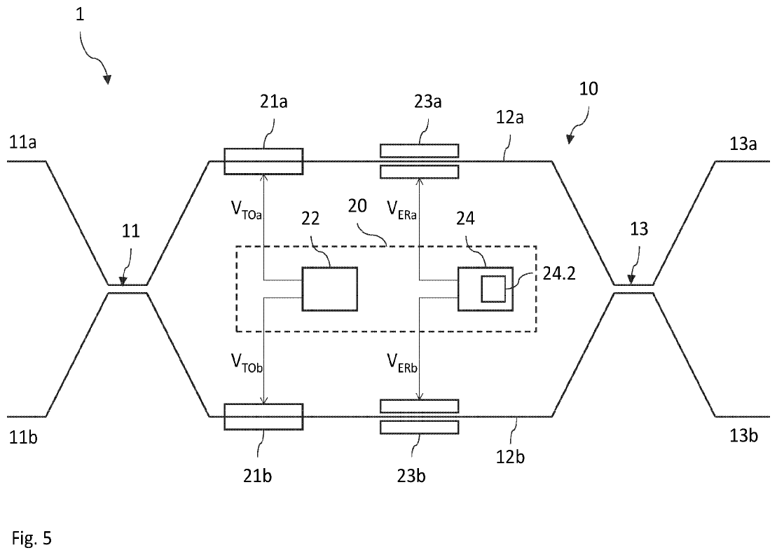

FIG. 5 is a schematic and partial view of an optoelectronic switch according to one variant of the embodiment illustrated in FIG. 2.

### DETAILED DESCRIPTION OF PARTICULAR EMBODIMENTS

In the figures and in the following part of the description, the same references represent identical or similar elements. In addition, the various elements are not shown to scale for the sake of the clarity of the figures. Furthermore, the various embodiments and variants are not exclusive of one another and may be combined together. Unless otherwise stated, the terms “substantially”, “around”, “of the order of” to within 10%, and preferably to within 5%.

The invention relates to an optoelectronic switch of the Mach-Zehnder type. It comprises a Mach-Zehnder interferometer having at least one input for receiving an optical signal referred to as incoming optical signal, and here two inputs (case of a 2×2 interferometer), and two separate outputs for supplying the optical signal referred to as outgoing optical signal, and a switching device designed to switch the outgoing optical signal from one to the other of the outputs.

Such an optoelectronic switch is preferably present in an optical chip allowing the routing of optical signals, the optical chip being formed in the framework of the technology known as photonics-on-silicon. The waveguides of the optoelectronic switch may thus be made of silicon and integrated into a substrate of the SOI (Silicon-On-Insulator) type. The switching device comprises at least two thermo-optical phase-shifters and at least two electro-refractive phase-shifters, disposed with at least one thermo-optical phase-shifter and at least one electro-refractive phase-shifter per arm.

FIG. 2 is a schematic and partial view of an optoelectronic switch 1 of the Mach-Zehnder type (MZ) according to one embodiment.

The optoelectronic switch 1 comprises a Mach-Zehnder interferometer 10 and a switching device 20 based on thermo-optical phase-shifters 21a, 21b and on electro-refractive phase-shifters 23a, 23b. In this example, the control of the electro-refractive phase-shifters 23a, 23b is carried out using measurement signals transmitted by photodetectors 25a, 25b optically coupled to the two ports 13a, 13b of the output coupler 13.

The Mach-Zehnder interferometer 10 comprises at least one input port 11a of a coupler 11 designed to receive an optical signal referred to as incoming signal of intensity Iᵢₙ. The input coupler 11 is preferably a multimode interference (MMI) coupler comprising two input ports 11a, 11b and dividing the incoming optical signal into two optical signals of same intensity in a first and a second waveguide 12a, 12b which form the arms of the interferometer 10. The incoming optical signal is a continuous optical signal and is monochromatic, whose wavelength may be equal, by way of example, to around 1.31 μm in the case of applications known as datacom applications, or equal to around 1.55 μm in the case of telecom applications.

The two arms 12a, 12b are optically connected to an output coupler 13 which comprises two output ports 13a, 13b. The output coupler 13 is preferably a multimode interference coupler, and combines the two incident optical signals so as to supply an outgoing optical signal on one or the other of the output ports 13a, 13b depending on whether the interferences between the two incident optical signals are constructive or destructive. Also, in the case where the interferometer 10 is a 2×2 interferometer comprising MMI couplers, the first arm 12a is directly connected to the first input port 11a and to the first output port 13a, and the second arm 12b is directly connected to the second input port 11b and to the second output port 13b.

Thus, by way of example, if the phase difference referred to as effective phase difference Δϕ_{eff}=ϕ_{A}−ϕ_{B}, defined as being the difference between the phase ϕ_{A} of the optical signal propagating in the first arm 12a and the phase ϕ_{B} of the optical signal propagating in the second arm 12b, is substantially zero Δϕ_{eff}=0, the switch 1, receiving an incoming optical signal on the input port 11a, then supplies an optical signal of maximum intensity on the output port 13b. The second output port 13b is then the port referred to as selected or active (state ON), and the first output port 13a is the port referred to as inactive or unselected (state OFF). Similarly, if the effective phase difference Δϕ_{eff} is substantially equal to π, the switch 1 then supplies an outgoing optical signal on the first output port 13a, the second port 13b then being the unselected port. The effective phase difference Δϕ_{eff}, as described in detail hereinbelow, may comprise a component referred to as thermo-optical component Δϕ_{TO} generated by the thermo-optical phase-shifters 21a, 21b, and a component referred to as electro-refractive component Δϕ_{ER} generated by the electro-refractive phase-shifters 23a, 23b. It is said to be ‘effective’ in the sense that it corresponds to the instantaneous phase difference, at the time t, between the optical signals propagating in the arms of the interferometer 10.

The switch 1 comprises a switching device 20 designed to provide the switching of the outgoing optical signal onto one or the other of the output ports, upon receipt of a switching instruction sent by a controller (not shown) to which it is connected, and to maintain the outgoing optical signal on the chosen output port 13a, 13b during the whole of the duration T needed. The duration T is that which separates two switching instructions. For this purpose, it comprises at least two thermo-optical phase-shifters 21a, 21b and a switching module 22.

The thermo-optical phase-shifters 21a, 21b, also called heaters, are disposed in the arms 12a, 12b, with at least one thermo-optical phase-shifter per arm. Each thermo-optical phase-shifter 21a, 21b is designed to modify the phase of the optical signal propagating in the arm in question due to the Joule effect induced by an electrical current applied to the latter. In other words, the thermo-optical phase-shifter 21a, 21b applies a temperature to the waveguide 12a, 12b which leads to a modification of the phase of the optical signal. For this purpose, the thermo-optical phase-shifter 21a, 21b may be formed from a strip made of a resistive material, for example metal, disposed along a region of interest of the waveguide 12a, and spaced out from the latter so as not to induce any optical losses. As previously mentioned with reference to the prior art, a thermo-optical phase-shifter 21a, 21b has a relatively long switching time Δϕ_{TO} (characteristic duration of variation), usually of the order of a few microseconds, but does not substantially exhibit any insertion losses nor variation of insertion losses, and hence does not substantially lead to any degradation of the extinction ratio (good isolation between the two output ports).

The switching module 22 is designed to apply a continuous signal, referred to as switching signal, of constant intensity to the thermo-optical phase-shifters 21a, 21b, in such a manner as to generate a component referred to as thermo-optical component Δϕ_{TO}(t) of the effective phase difference Δϕ_{eff}(t) between the optical signals propagating in the arms 12a, 12b. This thermo-optical component Δϕ_{TO}(t) varies from an initial value Δϕᵢ up to a predetermined final value Δϕ_{f}, resulting in a switching of the outgoing optical signal from one to the other of the output ports 13a, 13b.

For this purpose, the switching module 22 is connected to the thermo-optical phase-shifters 21a, 21b. Upon receipt of a switching instruction by the switching device 20, the module 22 applies a switching signal V_{TOa}, V_{TOb} to the thermo-optical phase-shifters 21a, 21b. This switching signal V_{TOa}, V_{TOb} is continuous and of constant intensity during the whole duration T separating two consecutive switching instructions. The intensity of the switching signal V_{TOa}, V_{TOb} applied to the thermo-optical phase-shifters 21a, 21b is equal either to V_{TO,ref} or to V_{TO,ref}+V_{TO,π}. The value V_{TO,ref} is a reference value, constant over time, which may be zero. The value V_{TO,π} is also constant over time and is substantially equal to the intensity to be applied so that the thermo-optical phase-shifter 21a, 21b generates a variation of π of the phase ϕ of the optical signal propagating in the arm in question 12a, 12b.

Thus, as detailed hereinbelow, when the optical signal is incoming via the first input port 11a, and in order to obtain an outgoing optical signal via the second output port 13b, the switching module 22 applies the same continuous switching signal V_{TOa}, V_{TOb} of constant intensity V_{TO,ref} to each of the two thermo-optical phase-shifters 21a, 21b. Since these two signals are of same intensity, the thermo-optical component Δϕ_{TO} of the phase difference Δϕ_{eff} is substantially zero. Subsequently, upon receipt of an instruction for switching from the second port 13b to the first output port 13a, the switching module 22 applies a continuous switching signal V_{TOb} of constant intensity V_{TO,ref} to the second thermo-optical phase-shifter 21b and a continuous switching signal V_{TOa} of constant intensity equal to V_{TO,ref}+V_{TO,π} to the first thermo-optical phase-shifter 21a. Thus, the thermo-optical component Δϕ_{TO} resulting from this is substantially equal to π. The outgoing optical signal then switches from the second port 13b to the first output port 13a.

It should be noted that the thermo-optical component Δϕ_{T} of the effective phase difference Δϕ_{eff} varies between 0 and π, with a phase shift Δφₒ which can correspond to a natural offset that the Mach-Zehnder interferometer to may exhibit. This phase shift Δφₒ may be taken into account when the switching signal V_{TOa}, V_{TOb} is applied to the thermo-optical phase-shifters 21a, 21b. In the case where this phase shift Δφₒ varies over time, notably owing to a thermal drift of the interferometer 10, a dynamic correction may be made via photodetectors optically coupled to the ports 13a, 13b of the output coupler 13.

According to the invention, the switching device 20 comprises additional elements allowing the switching time of the switch 1 to be greatly reduced. For this purpose, the switching device 20 comprises at least two electro-refractive phase-shifters 23a, 23b disposed in the arms 12a, 12b of the interferometer 10, and a compensation module 24 designed to apply a transient signal, referred to as compensation signal, of variable intensity to the electro-refractive phase-shifters 23a, 23b.

Generally speaking, an electro-refractive phase-shifter 23a, 23b is designed to modify the phase of the optical signal passing through it by the effect of a modification of the density of free carriers present in a region referred to as an active region of the waveguide 12a, 12b which modifies its index of refraction as a consequence. In addition, the waveguide 12a, 12b comprises, in the active region, a semiconductor junction extending along the longitudinal axis of the waveguide 12a, 12b. The semiconductor junction is of the pin or pn type, or can even be a capacitive junction. The modification of the density of the free carriers in the active region of the waveguide 12a, 12b, when the semiconductor junction is polarized, may be achieved by depletion of carriers or by injection of carriers, or even by accumulation of carriers in the case of a capacitive junction. Conventional examples of semiconductor junctions whose properties are modified by depletion, injection or accumulation of carriers are notably given in the publication by Reed et al. entitled Silicon optical modulators, Nature photonics 4, 518-526 (2010). As previously mentioned with reference to the prior art, the electro-refractive phase-shifters 23a, 23b exhibit a particularly short switching time Δt_{ER}, usually of the order of a few nanoseconds, but lead to insertion losses and variations of insertion losses as a function of the control voltage/current which may cause a degradation of the extinction ratio (poor isolation between the two output ports).

The compensation module 24 is designed to apply a compensation signal V_{ERa}, V_{ERb} to the electro-refractive phase-shifters 23a, 23b. This compensation signal is transient, in other words momentary, and has a variable intensity. It allows an additional component, referred to as electro-refractive component Δϕ_{ER}(t), of the effective phase difference Δϕ_{eff}(t) to be generated. Also, the effective phase difference Δϕ_{eff}(t) corresponds to the sum of the thermo-optical component Δϕ_{TO}(t) and of the electro-refractive component Δϕ_{ER}(t). As described in detail hereinbelow, the intensity of the compensation signal V_{ERa}, V_{ERb} is determined so that the electro-refractive component Δϕ_{ER}(t) generated allows the difference Δϕ_{f}−Δϕ_{eff}(t) between the predetermined final value Δϕ_{f} and the effective phase difference Δϕ_{eff}(t) to be minimized in real time.

The switching device 20 furthermore comprises two photodetectors 25a, 25b, optically coupled to the ports 13a, 13b of the output coupler 13, and connected to the compensation module 24. The photodetectors 25a, 25b therefore receive optical signals corresponding to a part of the outgoing optical signal on one or the other of the output ports 13a, 13b, and transmit to the compensation module 24 measurement signals representative of the optical power of the outgoing optical signal on the corresponding output port. The compensation module 24 comprises a processor 24.1 which, using the measurement signals, determines the value of the intensity of the compensation signal to be applied to the electro-refractive phase-shifters 23a, 23b in order to minimize, in real time, the difference between the final value Δϕ_{f} and the effective phase difference Δϕ_{eff}.

The compensation module 24 is also connected to the electro-refractive phase-shifters 23a, 23b. Upon receipt of a switching instruction by the switching device 20, the compensation module 24 applies a compensation signal V_{ERa}, V_{ERb} to the electro-refractive phase-shifters 23a, 23b. This compensation signal is transient, in other words momentary, during the period T between two consecutive switching instructions, and of variable intensity. The initial intensity applied to one or the other of the electro-refractive phase-shifters 23a, 23b is initially equal to V_{ER,ref}+V_{ER,π}. The value V_{ER,ref} is a reference value, constant over time, which may be zero. The value V_{ER,π} is an initial value substantially equal to the value to be applied for the electro-refractive phase-shifter 23a, 23b to generate a variation of π of the phase ϕ of the optical signal propagating in the arm in question 12a, 12b.

As detailed hereinbelow, the compensation signal V_{ERa}, V_{ERb} allows the electro-refractive component Δϕ_{ER}(t) of the effective phase difference Δϕ_{eff}(t) to be generated, which is added to the thermo-optical component Δϕ_{TO}(t). Given that the switching signal V_{TOa}, V_{TOb} is continuous and constant, the thermo-optical component Δϕ_{TO}(t) varies progressively from an initial value Δϕᵢ towards the final value Δϕ_{f} with a long time constant Δϕ_{TO}, of the order of a few microseconds. In contrast, the phase difference Δϕ_{ER}(t) reaches the final value Δϕ_{f} with a very short time constant Δϕ_{ER}, of the order of a few nanoseconds. As the thermo-optical component Δϕ_{TO}(t) varies from the initial value Δϕᵢ towards the final value Δϕ_{f}, the electro-refractive component Δϕ_{ER}(t) varies so as to thus constantly minimize the difference between the effective phase difference Δϕ_{eff}(t) and the final value Δϕ_{f}.

Thus, the switch 1 has a very short switching time, equal to the switching time Δϕ_{ER} of the order of a few nanoseconds. It also exhibits limited insertion losses together with a high extinction ratio given that, when the thermo-optical component Δϕ_{TO}(t) becomes dominant in the effective phase difference Δϕ_{eff}(t), the electro-refractive component Δϕ_{ER}(t) becomes small then negligible, thus limiting the imbalance in the insertion losses induced by the phase-shifters 23a and 23b and hence the associated optical crosstalk.

The operation of the switch 1 such as illustrated in FIG. 2 is now described in detail, with reference to FIGS. 3 and 4.

The terms used in the following part of the description are defined here:
t_{B→A} and t_{A→B} respectively represent the moments of switching from the second port to the first port of the output coupler 13, and vice versa;
Δϕ_{eff}(t) is the effective phase difference, instantaneous at the time t, between the optical signals propagating in the arms of the interferometer 10. It is the sum of two components, namely the thermo-optical component Δϕ_{TO}(t) coming from the thermo-optical phase-shifters 21a, 21b, and the electro-refractive component Δϕ_{ER}(t) coming from the electro-refractive phase-shifters 23a, 23b. The effective phase difference Δϕ_{eff}(t), and also the thermo-optical component Δϕ_{TO}(t), vary between 0 and π. The electro-refractive component Δϕ_{ER}(t) varies between 0 and Δϕ_{f}−Δϕ_{TO}(t). The variation of a phase difference between 0 and π extends modulo 2π.
Δϕ_{f} is the predetermined final value of the effective phase difference Δϕ_{eff}(t) for which the switching is implemented. It is equal to 0 or π.
V_{TO,π} and V_{ER,π} are respectively the intensity of the electrical signal applied to a thermo-optical phase-shifter 21a, 21b by the switching module 22, and to an electro-refractive phase-shifter 23a, 23b by the compensation module 24, in order to cause a variation of 7C of the phase of the optical signal flowing through it.

The switching of the outgoing optical signal from the second port to the first port of the output coupler 13 will first of all be described, with reference to FIG. 3 which illustrates the time variation:
of the switching signal V_{TOa}(t) and V_{TOb}(t) applied to the thermo-optical phase-shifters 21a, 21b, and of the thermo-optical component Δϕ_{TO}(t) of the effective phase difference Δϕ_{eff}(t) resulting from this;
of the compensation signal V_{ERa}(t) and V_{ERb}(t) applied to the electro-refractive phase-shifters 23a, 23b, and of the electro-refractive component Δϕ_{ER}(t) of the effective phase difference Δϕ_{eff}(t) resulting from this; and
of the effective phase difference Δϕ_{eff}(t) corresponding to the sum of the thermo-optical component Δϕ_{TO}(t) and of the electro-refractive component Δϕ_{ER}(t).

At t<t_{B→A}, in other words prior to the instruction to switch the outgoing optical signal from the second port 13b to the first port 13a of the output coupler 13, the incoming optical signal is supplied to the first port 11a of the input coupler 11 and the outgoing optical signal is output via the second port 13b of the output coupler 13. For this purpose, the switching module 22 respectively imposes a switching signal of intensity V_{TOa} and V_{TOb} on the thermo-optical phase-shifters 21a, 21b such that the thermo-optical component Δϕ_{TO}(t) of the effective phase difference Δϕ_{eff}(t) is zero. Here, the intensities V_{TOa} and V_{TOb} are zero, with the reference value V_{TO,ref} being considered as zero in the following part of the description. In addition, the compensation module 24 respectively imposes a transient compensation signal of intensity V_{ERa} and V_{ERb} on the electro-refractive phase-shifters 23a, 23b such that the component Δϕ_{ER}(t) of the effective phase difference Δϕ_{eff}(t) is zero. Here, the intensities V_{ERa} and V_{ERb} are zero, with the reference value V_{ER,ref} being zero in the following part of the description.

At t≥t_{B→A}, in other words starting from the moment of switching t_{B→A}, the switching module 22 applies a continuous switching signal V_{TOa}, V_{TOb} of constant intensity to the thermo-optical phase-shifters 21a, 21b, and the compensation module 24 simultaneously applies a transient compensation signal V_{ERa}, V_{ERb} of variable intensity to the electro-refractive phase-shifters 23a, 23b.

Thus, the switching module 22 applies a continuous switching signal V_{TOa}, V_{TOb} of constant intensity to the thermo-optical phase-shifters 21a, 21b for generating the thermo-optical component Δϕ_{TO}(t) between the optical signals propagating in the arms 12a, 12b, which goes progressively from a zero value to the predetermined value Δϕ_{f} here equal to π, resulting in a switching of the outgoing optical signal from the second port 13b to the first port 13a of the output coupler 13. Here, the switching signal V_{TOa}(t) applied to the first thermo-optical phase-shifter 21a has a constant intensity V_{TOa}(t)=V_{TO,π} so that it induces a variation of π of the phase ϕ_{A} of the optical signal propagating in the first arm 12a. In addition, the switching signal V_{TOb}(t) applied to the second thermo-optical phase-shifter 21b has a constant intensity V_{TOb}(t)=0 so that it does not induce any variation of the phase ϕ_{B} of the optical signal propagating in the second arm 12b. Thus, the phase difference Δϕ_{eff}(t) has a thermo-optical component Δϕ_{TO}(t) which varies progressively from 0 to Δϕ_{eff}=π, with a characteristic time Δϕ_{TO} which is the long switching time of the thermo-optical phase-shifters, usually of the order of a few microseconds.

Simultaneously with the application of the switching signal V_{TOa}, V_{TOb} by the switching module 22, the compensation module 24 applies a transient compensation signal V_{ERa}, V_{ERb} of variable intensity to the electro-refractive phase-shifters 23a, 23b for generating the electro-refractive component Δϕ_{ER}(t) allowing the difference between Δϕ_{f} and Δϕ_{eff}(t) to be minimized. The electro-refractive component Δϕ_{ER}(t) then goes rapidly from a zero value to the predetermined value Δϕ_{f}, here equal to π, in a time constant of the order of a nanosecond or less, then progressively falls to a zero value, at the same time as Δϕ_{TO}(t) rises.

Here, the compensation signal V_{ERa}(t) applied to the first electro-refractive phase-shifter 23a therefore exhibits a peak of intensity at the value V_{ER,π} such that it immediately induces a variation of TL of the phase ϕ_{A} of the optical signal propagating in the first arm 12a, then exhibits a decrease in intensity down to 0. In addition, the compensation signal V_{ERb}(t) applied to the second electro-refractive phase-shifter 23b has a constant intensity V_{ER,B}(t)=0 such that it does not induce any variation of the phase ϕ_{B} of the optical signal propagating in the second arm 12b. Thus, the phase difference Δϕ_{eff}(t) has, aside from the thermo-optical component Δϕ_{TO}(t), a component Δϕ_{ER}(t) which immediately exhibits a peak at Δϕ_{f}=π then progressively decreases to 0. The characteristic time of variation of Δϕ_{ER}(t) from 0 to Δϕ_{f} is the short switching time Δt_{ER} of the electro-refractive phase-shifters, which may be of the order of a few nanoseconds.

The variation of intensity of the compensation signal V_{ERa}(t) is defined such that the difference between the pre-determined value Δϕ_{f} and the effective phase difference Δϕ_{eff}(t) is minimized, or even eliminated. The value of the intensity of the signal V_{ERa}(t) is, in this example, determined based on the measurement signals coming from the photodetectors 25a, 25b. Thus, upon the application of the compensation signal of intensity V_{ERa}(t)=V_{ER,π}, the effective phase difference Δϕ_{eff}(t) reaches a value of π such that substantially all the optical power is switched from the second port 13b to the first port 13a. The photodetectors 25a, 25b therefore measure a maximum optical power on the first port 13a and a minimum optical power, substantially zero, on the second port 13b. As the thermo-optical component Δϕ_{TO}(t) increases, the photodetectors 25a, 25b measure a decrease in the optical power on the first selected port 13a, and an increase in the optical power on the second unselected port 13b. Based on the measurement signals transmitted by the photodetectors 25a, 25b, the processor 24.1 of the compensation module 24 determines the variable intensity to be applied to the first electro-refractive phase-shifter 23a, which results in a decrease in the component Δϕ_{ER}(t) allowing the difference Δϕ_{f}−Δϕ_{eff}(t) to be minimized, leading to an increase in the optical power on the first selected port 13a, and a decrease in the optical power on the second unselected port 13b. The extinction ratio is thus improved (optical crosstalk reduced) since the electro-refractive phase-shifters 23a, 23b (here the phase-shifter 23a) are reset to zero, which leads to an optimal balance between the losses in the arms.

Accordingly, the switching from the second port 13b to the first port 13a of the output coupler 13 is carried out by the thermo-optical phase-shifters 21a, 21b given that the effective phase difference Δϕ_{eff}(t) only substantially comprises, eventually, in other words after the transient switching phase, the thermo-optical component Δϕ_{TO}(t) which is substantially equal to Δϕ_{f}. After the transient switching phase, the thermo-optical phase-shifters 21a, 21b remain activated and the electro-refractive phase-shifters 23a, 23b are disabled, such that the switch 1 exhibits particularly low insertion losses and a high extinction ratio (low optical crosstalk). Furthermore, during the transient switching phase, the switching time is very short owing to the (momentary) activation of the electro-refractive phase-shifters 23a, 23b. Thus, the switch 1 has a very short switching time, corresponding to the electro-refractive switching time Δϕ_{ER}, usually of the order of a few nanoseconds. It may therefore be noted that the switching is provided by the thermo-optical phase-shifters 21a, 21b, but that the ‘switching delay’ is compensated by the momentary activation of the electro-refractive phase-shifters 23a, 23b. Finally, it is noted that the extinction ratio is momentarily degraded during the transient activation of the electro-refractive phase-shifters 23a, 23b. However, this momentary degradation is situated at the first moments of the transient switching phase, which does not affect, or affects very little, the key information contained in the optical signal transmitted, given that this key information is generally preceded by information of lower importance, for example synchronization information.

The switching of the outgoing optical signal from the first port 13a to the second port 13b of the output coupler 13 is now described, with reference to FIG. 4 which illustrates the time variation:
of the switching signal V_{TOa}(t) and V_{TOb}(t) applied to the thermo-optical phase-shifters 21a, 21b, and of the thermo-optical component Δϕ_{TO}(t) resulting from this;
of the compensation signal V_{ERa}(t) and V_{ERb}(t) applied to the electro-refractive phase-shifters 23a, 23b, and of the electro-refractive component Δϕ_{ER}(t) resulting from this; and
of the effective phase difference Δϕ_{eff}(t) corresponding to the sum of the thermo-optical component Δϕ_{TO} and of the electro-refractive component Δϕ_{ER}.

At t<t_{A→B}, in other words prior to the instruction for switching the outgoing optical signal from the first port 13a to the second port 13b of the output coupler 13, the incoming optical signal is supplied to the first port 11a of the input coupler 11 and the outgoing optical signal is output via the first port 13a of the output coupler 13. For this purpose, the switching module 22 imposes a switching signal of intensity V_{TOa} and V_{TOb} on the thermo-optical phase-shifters 21a, 21b such that the thermo-optical component Δϕ_{TO}(t) is equal to Δϕ_{f}=π. Here, the intensity V_{TOa}(t) is equal to V_{TO,π}, and the intensity V_{TOb} is zero (with the reference value V_{TO,ref} being considered as zero, as previously mentioned). In addition, the compensation module 24 imposes a compensation signal of intensity V_{ERa} and V_{ERb} on the electro-refractive phase-shifters 23a, 23b such that the electro-refractive component Δϕ_{ER}(t) is zero. Here, the intensities V_{ERa} and V_{ERb} are zero (with the reference value V_{ER,ref} being zero, as previously mentioned).

At t≥t_{A>B}, in other words starting from the moment of switching t_{A>B}, the switching module 22 applies a continuous switching signal V_{TOa}, V_{TOb} of constant intensity to the thermo-optical phase-shifters 21a, 21b, and the compensation module 24 simultaneously applies a transient compensation signal V_{ERa}, V_{ERb} of variable intensity to the electro-refractive phase-shifters 23a, 23b.

Thus, the switching module 22 applies a continuous switching signal V_{TOa}, V_{TOb} of constant intensity to the thermo-optical phase-shifters 21a, 21b for generating the thermo-optical component Δϕ_{TO}(t) between the optical signals propagating in the arms 12a, 12b, which goes progressively from an initial value Δϕᵢ equal to it to the final value Δϕ_{f} equal to 0, resulting in a switching of the outgoing optical signal from the first port 13a to the second port 13b of the output coupler 13. Here, the switching signal V_{TOa}(t) applied to the first thermo-optical phase-shifter 21a maintains its constant intensity V_{TOa}(t)=V_{TO,π}, and the switching signal V_{TOb}(t) applied to the second thermo-optical phase-shifter 21b goes from a zero intensity to a constant intensity V_{TOb}(t)=V_{TO,π} for a duration longer than the thermo-optical time constant Δϕ_{TO}. Thus, the phase difference Δϕ_{eff}(t) has a thermo-optical component Δϕ_{TO}(t) which varies progressively from Δϕᵢ=π to Δϕ_{f}=0, with a thermo-optical time constant Δϕ_{TO} which is the long switching time of the thermo-optical phase-shifters, usually of the order of a few microseconds.

Simultaneously with the application of the switching signal V_{TOa}, V_{TOb} by the switching module 22, the compensation module 24 applies a transient compensation signal V_{ERa}, V_{ERb} of variable intensity to the electro-refractive phase-shifters 23a, 23b for generating the electro-refractive component Δϕ_{ER}(t) allowing the difference between Δϕ_{f} and Δϕ_{eff}(t) to be minimized. The electro-refractive component Δϕ_{ER}(t) then goes rapidly from a zero value to the value −π, in a time constant of the order of a nanosecond or less, then progressively returns to the zero value at the same time as Δϕ_{TO}(t) decreases.

Here, the compensation signal V_{ERb}(t) applied to the second electro-refractive phase-shifter 23b therefore has a peak of intensity at the value V_{ER,π} such that it immediately induces a variation of π of the phase ϕ_{B} of the optical signal propagating in the second arm 12b, then exhibits a decrease in intensity down to 0. In addition, the compensation signal V_{ERa}(t) applied to the first electro-refractive phase-shifter 23a has a constant intensity V_{ERa}(t)=0 such that it does not induce any variation in the phase ϕ_{A} of the optical signal propagating in the first arm 12a. Thus, the phase difference Δϕ_{eff}(t) has, aside from the thermo-optical component Δϕ_{TO}(t), a component Δt_{ER}(t) which immediately exhibits a peak at −π, then varies progressively down to 0. The characteristic time of variation of Δϕ_{ER}(t) from 0 to −π is the short switching time Δϕ_{ER} of the electro-refractive phase-shifters, which may be of the order of a few nanoseconds.

The variation of intensity of the compensation signal V_{ERb}(t) is defined such that the difference between the value determined Δϕ_{f} and the effective phase difference Δϕ_{eff}(t) is minimized, or even eliminated. The value of the intensity of the signal V_{ERb}(t) is, in this example, determined from the measurement signals coming from the photodetectors 25a, 25b. Thus, during the application of the V_{ERb}(t)=V_{ER,π} by the compensation signal, the effective phase difference Δϕ_{eff}(t) reaches a zero value such that substantially all the optical power is switched from the first port 13a to the second output port 13b. The photodetectors 25a, 25b therefore measure a maximum optical power on the second port 13b and a minimum optical power, substantially zero, on the first port 13a. As the thermo-optical component Δϕ_{TO}(t) decreases, the photodetectors 25a, 25b measure a reduction in the optical power on the second selected port 13b, and an increase in the optical power on the first unselected port 13a. Using the measurement signals transmitted by the photodetectors 25a, 25b, the processor 24.1 of the compensation module 24 determines the variable intensity to be applied to the first electro-refractive phase-shifter 23a, which results in a reduction in the component Δϕ_{ER}(t) allowing the difference Δϕ_{f}−Δϕ_{eff}(t) to be minimized, leading to an increase in the optical power on the second selected port 13b, and a decrease in the optical power on the first unselected port 13a. The extinction ratio is thus improved (optical crosstalk reduced), since the electro-refractive phase-shifters 23a, 23b are brought back to zero, which leads to an optimal balance between the losses in the arms.

Also, the switching from the first port 13a to the second port 13b of the output coupler 13 is carried out by the thermo-optical phase-shifters 21a, 21b with the long thermo-optical switching time Δϕ_{TO}. The ‘switching delay’ is compensated by the (momentary) activation of the electro-refractive phase-shifters 23a, 23b, such that the switch 1 exhibits a very short switching time, corresponding to the electro-refractive switching time Δϕ_{ER}, usually of the order of a few nanoseconds. Furthermore, given that the effective phase difference Δϕ_{eff}(t) only substantially comprises eventually, in other words after the transient switching phase, the thermo-optical contribution Δϕ_{TO} which is equal to Δϕ_{f} (since the electro-refractive phase-shifters 23a, 23b are disabled), the switch 1 exhibits particularly low insertion losses, and a high extinction ratio (low optical crosstalk).

Lastly, starting from the time t′ later than time Δt_{TO} of thermo-optical switching, the switching signals V_{TOa}(t) and V_{TOb}(t) have an intensity that varies in an identical manner to V_{TO}, to zero, in such a manner as to keep a contribution Δϕ_{TO}(t) substantially zero. The effective phase difference Δϕ_{eff}(t) is thus not modified. The later switching from the second port 13b to the first port 13a will thus be able to be carried out.

FIG. 5 shows a schematic and partial view of an optoelectronic switch 1 of the Mach-Zehnder type (MZ) according to one variant of the embodiment illustrated in FIG. 2. The switch 1 essentially differs from this in that the variable intensity of the compensation signal V_{ERa}, V_{ERb} applied to the electro-refractive phase-shifters 23a, 23b is not determined based on measurement signals transmitted by photodetectors 25a, 25b, but is supplied by a memory 24.2 containing a law for time variation of the variable intensity. This time variation law has been previously determined based, for example, on experimental trials or on numerical/digital simulations of the electronic and optical behaviour of the switch 1.

Particular embodiments have just been described. Numerous variants and modifications will be apparent to those skilled in the art.

Thus, the switch 1 may comprise one or more additional thermo-optical phase-shifters, optically coupled to the photodetectors, notably allowing potential phase errors between the optical signals propagating in the arms of the interferometer 10 to be corrected, for example errors coming from a thermal drift of one or the other of the arms.

1: An optoelectronic switch, comprising:
a Mach-Zehnder interferometer, comprising:
an input coupler, comprising at least a first input port configured to receive an incoming optical signal;
first and second waveguides referred to as arms, connected to the input coupler, configured to transmit optical signals, coming from the incoming optical signal, and able to have an effective phase difference Δϕ_{eff}(t);
an output coupler, connected to the arms, and comprising two output ports, in order to supply an outgoing optical signal,
a switching device, comprising:
at least two thermo-optical phase-shifters disposed in the arms,
a switching module configured to apply a continuous switching signal of constant intensity, to the thermo-optical phase-shifters,
in such a manner as to generate a thermo-optical component Δϕ_{TO}(t) of the effective phase difference Δϕ_{eff}(t), which varies up to a predetermined final value Δϕ_{f} resulting in a switching of the outgoing optical signal onto one or the other of the output ports;
at least two electro-refractive phase-shifters disposed in the arms,
a compensation module configured to apply to the electro-refractive phase-shifters a transient compensation signal of variable intensity,
in such a manner as to generate an additional electro-refractive component Δϕ_{ER}(t) of the effective phase difference Δϕ_{eff}(t), the effective phase difference Δϕ_{eff}(t) thus being equal to the sum of the thermo-optical component Δϕ_{TO}(t) and of the electro-refractive component Δϕ_{ER}(t), the said variable intensity being determined in such a manner as to minimize the difference Δϕ_{f}−Δϕ_{eff}(t) between the predetermined final value Δϕ_{f} and the effective phase difference Δϕ_{eff}(t).

2: The optoelectronic switch according to claim 1, in which the switching device furthermore comprises at least one photodetector coupled to one of the output ports and connected to the compensation module, the compensation module comprising a processor for determining, using measurement signals transmitted by the photodetector, the variable intensity to be applied in such a manner as to minimize the said difference between the predetermined final value Δϕ_{f} and the effective phase difference Δϕ_{eff}(t).

3: The optoelectronic switch according to claim 1, in which the electro-refractive phase-shifters are pin diodes, pn diodes, or carrier accumulating capacitive structures.

4: The optoelectronic switch according to claim 1, in which the arms are made of silicon.

5: The optoelectronic switch according to claim 1, in which the Mach-Zehnder interferometer is a 2×2 interferometer whose input coupler comprises two input ports.

6: A method of switching an output optical signal from one to the other of the output ports of an optoelectronic switch according to claim 1 comprising the following steps:
i) application of the switching signal to the thermo-optical phase-shifters in such a manner as to generate the thermo-optical component Δϕ_{TO}(t) of the effective phase difference Δϕ_{eff}(t), which varies up to the predetermined final value Δϕ_{f} resulting in the switching of the outgoing optical signal;
ii) application of the transient compensation signal to the electro-optical phase-shifters in such a manner as to generate the electro-refractive component Δϕ_{ER}(t) of the effective phase difference Δϕ_{eff}(t), whose variable intensity is determined in such a manner as to minimize the said difference Δϕ_{f}−Δϕ_{eff}(t) between the predetermined final value Δϕ_{f} and the effective phase difference Δϕ_{eff}(t).

7: The switching method according to claim 6, in which the switching signal is designed to drive a variation going from 0 to π, and vice versa, of the thermo-optical contribution Δϕ_{TO}(t) of the effective phase difference Δϕ_{eff}(t), over a characteristic duration Δϕ_{TO} of thermo-optical variation.

8: The switching method according to claim 7, in which the compensation signal is configured to drive:
a variation going from 0 to ±π of the electro-refractive component Δϕ_{ER}(t) of the effective phase difference Δϕ_{eff}(t), over a characteristic duration Δϕ_{ER} of electro-refractive variation, less than the characteristic duration Δϕ_{TO} of thermo-optical variation,
followed by a return to 0, over a characteristic duration of variation substantially equal to the characteristic duration Δϕ_{TO} of thermo-optical variation.

9: The switching method according to claim 6, in which, in the absence of a phase difference between the optical signals propagating in the arms, the outgoing optical signal is sent to the second port of the output coupler, the switching from the second port to the first port of the output coupler comprising the following steps:
application of the switching signal, so that the thermo-optical component Δϕ_{TO}(t) of the effective phase difference Δϕ_{eff}(t) goes from 0 to π;
application of the compensation signal, so that the electro-refractive component Δϕ_{ER}(t) of the effective phase difference Δϕ_{eff}(t) goes from 0 to π, then decreases down to 0 at the same time as the thermo-optical component Δϕ_{TO}(t) progressively increases from 0 to π.

10: The switching method according to claim 9, in which:
the application of the switching signal amounts to applying a continuous signal V_{TOa} of constant intensity V_{TO,π} to the thermo-optical phase-shifter situated in the first arm driving a variation of π of the phase ϕ_{A} of the optical signal propagating in the first arm, and to applying a signal V_{TOb} of zero intensity to the thermo-optical phase-shifter situated in the second arm;
the application of the compensation signal amounts to applying a transient signal V_{ERa} of variable intensity going from 0 to a value V_{ER,π} to the electro-refractive phase-shifter situated in the first arm driving a variation of π of the phase ϕ_{A} of the optical signal propagating in the first arm, followed by a decrease to a zero value at the same time as the thermo-optical component Δϕ_{TO}(t) progressively increases from 0 to π, and in applying a signal V_{ERb} of zero intensity to the electro-refractive phase-shifter situated in the second arm.

11: The switching method according to claim 6, in which, in the absence of a phase difference between the optical signals propagating in the arms, the outgoing optical signal being sent to the second port of the output coupler, the switching from the first port to the second port of the output coupler comprises:
application of the switching signal, so that the thermo-optical component Δϕ_{TO}(t) goes from π to 0;
application of the compensation signal, so that the electro-refractive component Δϕ_{ER}(t) goes from 0 to −π, then increases up to 0, at the same time as the thermo-optical component Δϕ_{TO}(t) progressively decreases from π to 0.

12: The switching method according to claim 11, in which:
the application of the switching signal amounts to applying a continuous signal V_{TOa} of constant intensity V_{TO,π} to the thermo-optical phase-shifter situated in the first arm, and in applying a continuous signal V_{TOb} of constant intensity V_{TO,π} to the thermo-optical phase-shifter situated in the second arm driving a variation of Ft of the phase ϕ_{B} of the optical signal propagating in the second arm;
the application of the compensation signal amounts to applying a signal V_{ERa} of zero intensity to the electro-refractive phase-shifter situated in the first arm, and in applying a signal V_{ERb} of variable intensity going from 0 to a value V_{ER,π} to the electro-refractive phase-shifter situated in the second arm driving a variation of π of the phase ϕ_{B} of the optical signal propagating in the second arm, followed by a return to a zero value at the same time as the thermo-optical component Δϕ_{TO}(t) progressively decreases from π to 0.
